(19) United States
(12) Patent Application Publication
(10) Pub. No.: US 2024/0400735 A1
(43) Pub. Date: Dec. 5, 2024

(54) FLUORINE-CONTAINING POLYMER, COMPOSITION, MOISTUREPROOF COATING AGENT, AND ARTICLE

(71) Applicant: AGC Inc., Tokyo (JP)

(72) Inventors: Shinya TAJIMA, Tokyo (JP); Yusuke YASU, Tokyo (JP)

(73) Assignee: AGC Inc., Tokyo (JP)

(21) Appl. No.: 18/804,660

(22) Filed: Aug. 14, 2024

Related U.S. Application Data
(63) Continuation of application No. PCT/JP2023/002271, filed on Jan. 25, 2023.

(30) Foreign Application Priority Data
Feb. 21, 2022 (JP) 2022-024719

(51) Int. Cl. C08F 214/18; C08L 27/12; C09D 7/65

(52) U.S. Cl. CPC C08F 214/184; C08L 27/12; C09D 7/65

(57) ABSTRACT

A fluorine-containing polymer, a composition, and a moisture-proof coating agent that can form a coating film with excellent adhesion stability, and an article with excellent adhesion stability between a base material and a coating film. The fluorine-containing polymer includes a unit A having a fluorine-containing aliphatic ring structure constituting the main chain, and a unit B based on a fluorine-containing monomer b having an adhesive functional group. The composition includes the fluorine-containing polymer and a liquid medium. The moisture-proof coating agent includes the fluorine-containing polymer. The article has a coating film of the composition on a base material.

This application is a continuation application of International Application No. PCT/JP2023/002271, filed on Jan. 25, 2023, which claims priority to Japanese Patent Application No. 2022-024719, filed on Feb. 21, 2022, the entire contents of which are incorporated herein by reference.

### TECHNICAL FIELD

The present invention relates to a fluorine-containing polymer, a composition, a moisture-proof coating agent, and an article.

### BACKGROUND ART

Fluororesins have excellent low surface energy, insulation properties, chemical resistance, and the like, and are used for a variety of purposes. In particular, fluorine-containing polymers having fluorine-containing aliphatic ring structures within the main chains thereof not only have the above-mentioned properties but also are amorphous, and therefore can be dissolved in solvents, and the solutions thereof are used for coating purposes.

Patent Document 1 describes an oil repellent agent composition containing: a fluorine-containing polymer having a fluorine-containing aliphatic ring structure within the main chain thereof, a low molecular weight fluorine-containing polymer having no fluorine-containing aliphatic ring structure within the main chain thereof, and a solvent. In addition, Patent Document 1 describes introduction of a functional group such as a carboxy group into a fluorine-containing polymer in order to improve adhesion to a base material, and in Examples, a fluorine-containing polymer into which a carboxy group has been introduced at the end of the main chain is used.

### CITATION LIST

### [Patent Document]

[Patent Document 1] Japanese Unexamined Patent Application, First Publication No. 2006-257329

### SUMMARY OF INVENTION

### Technical Problem

However, the oil repellent agent composition described in Patent Document 1 is inferior in terms of adhesion stability of the coating film. For example, when an oil repellent agent composition is coated onto a plurality of base materials, the adhesion of the coating film may vary for each base material even if the base materials and coating conditions are the same.

The present invention provides a fluorine-containing polymer, a composition, and a moisture-proof coating agent that can form a coating film with excellent adhesion stability, and an article with excellent adhesion stability between a base material and a coating film.

### Solution to Problem

The present invention includes the following aspects.

[1] A fluorine-containing polymer comprising a unit A having a fluorine-containing aliphatic ring structure constituting a main chain and a unit B based on a fluorine-containing monomer b having an adhesive functional group.

[2] The fluorine-containing polymer according to [1] above, wherein a content of the unit B is from 0.1 to 20% by mass with respect to the total units constituting the fluorine-containing polymer.

[3] The fluorine-containing polymer according to [1] or [2] above, wherein the unit having a fluorine-containing aliphatic ring structure constituting a main chain is at least one selected from the group consisting of a unit formed by cyclopolymerization of a diene-based fluorine-containing monomer, and a unit based on a cyclic fluorine-containing monomer.

[4] The fluorine-containing polymer according to [3] above, wherein the fluorine-containing monomer b is represented by the following Formula b1:

CX^{a}X^{b}═CX^{c}—R¹—Z Formula b1

In the Formula b1, each of X^{a}, X^{b} and X^{c} independently represents a fluorine atom or a chlorine atom, and at least one of X^{a}, X^{b} and X^{c} is a fluorine atom,
R¹ is a divalent perfluoroorganic group which may have at least one hetero atom selected from the group consisting of an oxygen atom and a sulfur atom,
Z is CₐH₂ₐOH, COOH, COOR², SO₃H, C_{b}H_{2b}NH₂ or C_{d}H_{2d}CO₂NH₂, a is an integer from 0 to 6, R² is an alkyl group having 1 to 12 carbon atoms, b is an integer from 0 to 6 and d is an integer from 0 to 6.

[5] The fluorine-containing polymer according to any one of [1] to [4] above, further comprising a unit C based on the following fluorine-containing monomer c,

Fluorine-containing monomer c: a fluorine-containing monomer that has at least one hetero atom selected from the group consisting of an oxygen atom and a sulfur atom, but does not have a fluorine-containing aliphatic ring structure constituting the main chain, and an adhesive functional group.

[6] The fluorine-containing polymer according to [5] above, wherein a mass ratio expressed by a formula: (the unit A)/(the unit C) is from 25/75 to 80/20.

[7] The fluorine-containing polymer according to [5] or [6] above, wherein the fluorine-containing monomer c is represented by the following Formula c1,

CX^{d}X^{e}═CX^{f}—C_{c}F_{2c}—Y^{c}—R^{F} Formula c1

In the Formula c1, each of X^{d}, X^{e} and X^{f} independently represents a fluorine atom or a chlorine atom, and at least one of X^{d}, X^{e} and X^{f} is a fluorine atom,
c is an integer from 0 to 4, Y° is an oxygen atom or a sulfur atom, and
R^{F} is a perfluoroalkyl group having 1 to 10 carbon atoms.

[8] A composition comprising the fluorine-containing polymer according to any one of [1] to [7] above, and a liquid medium.

[9] A moisture-proof coating agent comprising the fluorine-containing polymer according to any one of [1] to [7] above.

[10] A moisture-proof coating agent comprising the composition according to [8] above.

[11] An article having a coating film of the composition according to [8] above on a base material.

[12] The article according to [11] above, wherein the base material is a printed board.

### Advantageous Effects of Invention

The polymer of the present invention can form a coating film with excellent adhesion stability.

The composition of the present invention can form a coating film with excellent adhesion stability.

The moisture-proof coating agent of the present invention can form a coating film with excellent adhesion stability.

The article of the present invention exhibits excellent adhesion stability between the base material and the coating film.

### DESCRIPTION OF EMBODIMENTS

The meanings and definitions of terms are as follows.

The term “aliphatic ring structure” means a saturated or unsaturated ring structure that has no aromaticity.

The term “fluorine-containing aliphatic ring structure” means an aliphatic ring structure in which a fluorine atom or a fluorine-containing group is bonded to at least a portion of the carbon atoms constituting the main skeleton of the ring. Examples of the fluorine-containing group include a perfluoroalkyl group, a perfluoroalkoxy group, and ═CF₂. A substituent other than a fluorine atom and a fluorine-containing group may be bonded to a portion of the carbon atoms constituting the main skeleton of the ring.

An “etheric oxygen atom” is an oxygen atom present between carbon atoms (—C—O—C—).

The term “mass average molecular weight” refers to a polymethyl methacrylate (hereinafter also referred to as “PMMA”) equivalent value measured by gel permeation chromatography.

In the present specification, a group represented by the Formula 2 is also referred to as a “group 2”, and a compound represented by a Formula ma1 is also referred to as a “compound ma1”. Groups, compounds, monomers, and the like represented by other formulae are also described in the same manner.

A “monomer” means a compound having a polymerizable carbon-carbon double bond.

A symbol “-” indicating a numerical range means that numerical values described before and after this symbol are included as the lower limit value and the upper limit value.

The lower limit values and upper limit values of various numerical ranges disclosed in present specification can be arbitrarily combined to form a new numerical range.

### (Fluorine-Containing Polymer)

A fluorine-containing polymer (hereinafter also referred to as “the present polymer”) according to one embodiment of the present invention comprises a unit A and a unit B.

The present polymer may further comprise a unit C, if necessary.

The present polymer may further comprise a unit D described later, if necessary.

### <Unit A>

The unit A is a unit having a fluorine-containing aliphatic ring structure. The fluorine-containing aliphatic ring structure constitutes the main chain of the present polymer. The unit A is preferably a perfluoro unit.

The fluorine-containing aliphatic ring structure may be a carbocyclic structure in which the ring skeleton is composed only of carbon atoms, or may be a heterocyclic structure in which the ring skeleton comprises an atom (hetero atom) other than carbon atoms. Examples of the hetero atom include an oxygen atom and a nitrogen atom. The number of atoms constituting the ring skeleton of the fluorine-containing aliphatic ring structure is preferably from 4 to 7, and particularly preferably from 5 to 6. That is, the aliphatic ring structure is preferably a 4- to 7-membered ring, and particularly preferably a 5- to 6-membered ring.

From the viewpoints of transparency and solvent solubility, the fluorine-containing aliphatic ring structure is preferably a fluorine-containing aliphatic ring structure having a heterocyclic structure with an etheric oxygen atom in the ring skeleton, and particularly preferably a fluorine-containing aliphatic ring structure having a heterocyclic structure with one or two etheric oxygen atoms in the ring skeleton.

Examples of the fluorine-containing aliphatic ring structure include a ring structure in which some or all of the hydrogen atoms in a hydrocarbon ring structure or a heterocyclic structure are substituted with fluorine atoms.

Among these, a fluorine-containing aliphatic ring structure in which some or all of the hydrogen atoms in a heterocyclic structure having an etheric oxygen atom in the ring skeleton are substituted with fluorine atoms is preferred, and a fluorine-containing aliphatic ring structure in which some or all of the hydrogen atoms in a heterocyclic structure having one or two etheric oxygen atoms in the ring skeleton are substituted with fluorine atoms is particularly preferred.

As the fluorine-containing aliphatic ring structure, a perfluoroaliphatic ring structure in which all of the hydrogen atoms in a hydrocarbon ring structure or a heterocyclic structure are substituted with fluorine atoms is preferred.

The above description in which the fluorine-containing aliphatic ring structure “constitutes the main chain” means that at least one of the carbon atoms constituting the ring skeleton of the fluorine-containing aliphatic ring structure is a carbon atom constituting the main chain of the polymer. In other words, it means that since two carbon atoms derived from a polymerizable double bond constitute the main chain of the polymer, one or two adjacent carbon atoms constituting the ring of the fluorine-containing aliphatic ring structure are carbon atoms derived from one polymerizable double bond.

For example, when the unit A is formed by addition polymerization of monoene-based monomers, either two carbon atoms derived from the polymerizable double bond constitute the main chain and these two carbon atoms are two adjacent carbon atoms in the ring skeleton, or one of the two carbon atoms is a carbon atom in the ring skeleton. In addition, when the unit A is formed by cyclopolymerization of a diene-based monomer, a total of four carbon atoms derived from two polymerizable double bonds constitute the main chain, and two to four of these four carbon atoms are the carbon atoms constituting the ring skeleton.

Examples of the unit A include a unit formed by cyclopolymerization of a diene-based fluorine-containing monomer, and a unit based on a cyclic fluorine-containing monomer.

A diene-based fluorine-containing monomer is a monomer having two polymerizable double bonds and a fluorine atom. In the case of a diene-based fluorine-containing monomer, the unit A is formed by cyclopolymerization. The polymerizable double bond is not particularly limited, but is preferably a vinyl group, an allyl group, an acryloyl group, or a methacryloyl group. In these polymerizable double bonds, some or all of the hydrogen atoms bonded to carbon atoms may be replaced with fluorine atoms.

As the diene-based fluorine-containing monomer, the following compound ma1 is preferred.

CF₂═CF-Q-CF═CF₂ Formula ma1

In the Formula ma1, Q is a perfluoroalkylene group having 1 to 6 carbon atoms which may have some of the fluorine atoms substituted with halogen atoms other than fluorine atoms and may have an etheric oxygen atom.

In the Formula ma1, the number of carbon atoms in the perfluoroalkylene group represented by Q is from 1 to 6, preferably from 1 to 5, and particularly preferably from 1 to 3. The perfluoroalkylene group is preferably linear or branched, and particularly preferably linear.

In the perfluoroalkylene group, some of the fluorine atoms may be substituted with halogen atoms other than fluorine atoms. Examples of the halogen atoms other than fluorine atoms include chlorine atoms and bromine atoms.

The perfluoroalkylene group may have an etheric oxygen atom.

Q is preferably a perfluoroalkylene group having an etheric oxygen atom. In that case, the etheric oxygen atom in the perfluoroalkylene group may be present at one end of the perfluoroalkylene group, may be present at both ends of the perfluoroalkylene group, or may be present between carbon atoms of the perfluoroalkylene group. From the viewpoint of cyclopolymerizability, it is preferable to be present at one end of the perfluoroalkylene group.

As Q, the following groups q1 and q2 are preferred.

—(CR¹¹R¹²)ₕ— Formula q1

—(CR¹³R¹⁴)ᵢO(CR¹⁵R¹⁶)ⱼ— Formula q2

In each formula, each of R¹¹, R¹², R¹³, R¹⁴, R¹⁵ and R¹⁶ independently represents a fluorine atom, a chlorine atom, a trifluoromethyl group or a trifluoromethoxy group. h is an integer from 2 to 4, and a plurality of R¹¹ and R¹² groups may be the same as or different from each other. Each of i and j is an integer from 0 to 3, and i+j is an integer from 1 to 3. When i is 2 or 3, a plurality of R¹³ and R¹⁴ groups may be the same as or different from each other. When j is 2 or 3, a plurality of R¹⁵ and R¹⁶ groups may be the same as or different from each other.

h is preferably 2 or 3. It is preferable that R¹¹ and R¹² are all fluorine atoms, or all but one or two are fluorine atoms. It is preferable that i is 0 and j is 1 or 2. It is preferable that R¹⁵ and R¹⁶ are all fluorine atoms, or all but one or two are fluorine atoms.

Examples of the compound ma1 include the following compounds.
CF₂═CFOCF₂CF═CF₂,
CF₂═CFOCF(CF₃)CF═CF₂,
CF₂═CFOCF₂CF₂CF═CF₂,
CF₂═CFOCF₂CF(CF₃)CF═CF₂,
CF₂═CFOCF(CF₃)CF₂CF═CF₂,
CF₂═CFOCFClCF₂CF═CF₂,
CF₂═CFOCCl₂CF₂CF═CF₂,
CF₂═CFOCF₂OCF═CF₂,
CF₂═CFOC(CF₃)₂OCF═CF₂,
CF₂═CFOCF₂CF(OCF₃)CF═CF₂,
CF₂═CFCF₂CF═CF₂,
CF₂═CFCF₂CF₂CF═CF₂,
CF₂═CFCF₂OCF₂CF═CF₂.

Examples of the cyclic fluorine-containing monomer include a monomer containing a fluorine-containing aliphatic ring and having a polymerizable double bond between carbon atoms constituting the fluorine-containing aliphatic ring, and a monomer containing a fluorine-containing aliphatic ring and having a polymerizable double bond between a carbon atom constituting the fluorine-containing aliphatic ring and a carbon atom outside the fluorine-containing aliphatic ring.

As the cyclic fluorine-containing monomer, the following compounds ma2 and compound ma3 are preferred.

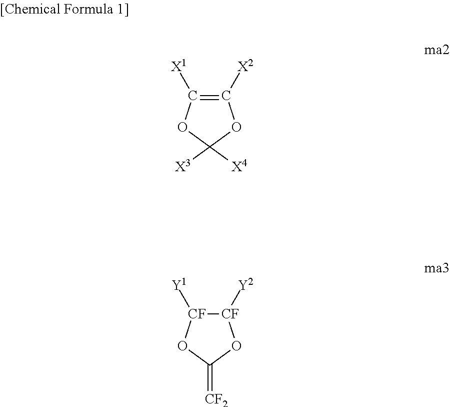

In each formula, each of X¹, X², X³, X⁴, Y¹ and Y² independently represents a fluorine atom, a perfluoroalkyl group which may have an etheric oxygen atom, or a perfluoroalkoxy group which may have an etheric oxygen atom. X³ and X⁴ may be bonded to each other to form a ring.

In the Formulae ma2 and ma3, the number of carbon atoms in the perfluoroalkyl group represented by X¹, X², X³, X⁴, Y¹ and Y² is preferably from 1 to 7, more preferably from 1 to 5, and particularly preferably from 1 to 4. The perfluoroalkyl group is preferably linear or branched, and particularly preferably linear. As the perfluoroalkyl group, a trifluoromethyl group, a pentafluoroethyl group, a heptafluoropropyl group, and the like are preferred, and a trifluoromethyl group is particularly preferred.

Examples of the perfluoroalkoxy group represented by X¹, X², X³, X⁴, Y¹ and Y² include those in which an oxygen atom (—O—) is bonded to the perfluoroalkyl group described above. A trifluoromethoxy group is particularly preferred.

When the number of carbon atoms in the above perfluoroalkyl group and the above perfluoroalkoxy group is 2 or more, an etheric oxygen atom (—O—) may be present between the carbon atoms of the perfluoroalkyl group or between the carbon atoms of the perfluoroalkoxy group.

In the Formula ma2, X¹ is preferably a fluorine atom.

X² is preferably a fluorine atom, a trifluoromethyl group, or a perfluoroalkoxy group having 1 to 4 carbon atoms, and particularly preferably a fluorine atom or a trifluoromethoxy group.

Each of X³ and X⁴ independently preferably represents a fluorine atom or a perfluoroalkyl group having 1 to 4 carbon atoms, and particularly preferably represents a fluorine atom or a trifluoromethyl group.

X³ and X⁴ may be bonded to each other to form a ring. The number of atoms constituting the ring skeleton of the above ring is preferably from 4 to 7, and more preferably from 5 to 6.

In the Formula ma3, each of Y¹ and Y² independently preferably represents a fluorine atom, a perfluoroalkyl group having 1 to 4 carbon atoms, or a perfluoroalkoxy group having 1 to 4 carbon atoms, and particularly preferably represents a fluorine atom or a trifluoromethyl group.

Preferred examples of the compound ma2 include the following compounds ma21 to ma25.

Preferred examples of the compound ma3 include the following compounds ma31 and ma32.

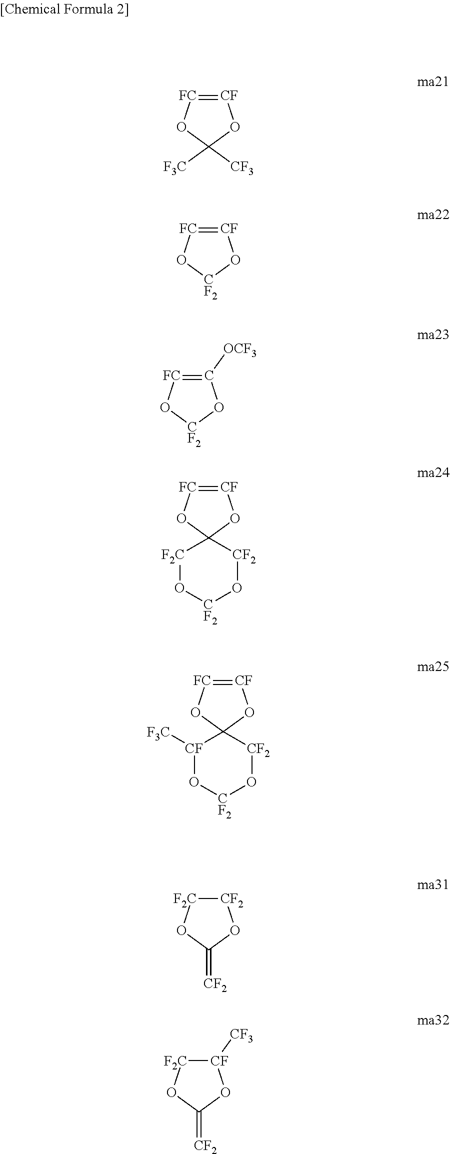

The unit A is preferably at least one selected from the group consisting of the following units a11 to a16.

The units a11 to a14 are units formed by cyclopolymerization of the compound ma1, and at least one of the units a11 to a14 is produced by cyclopolymerization of the compound ma1. At this time, units having a structure in which the number of atoms constituting the ring skeleton of the fluorine-containing aliphatic ring is 5 or 6 are likely to be produced among the units a11 to a14. Polymers comprising two or more of these units may also be produced.

In other words, the compound ma1 is preferably a compound ma1 having a structure in which the number of atoms constituting the ring skeleton including the atoms in Q is 5 or 6 in the following units a11 to a14.

The following unit a15 is a unit formed from the compound ma2, and the following unit a16 is a unit formed from the compound ma3.

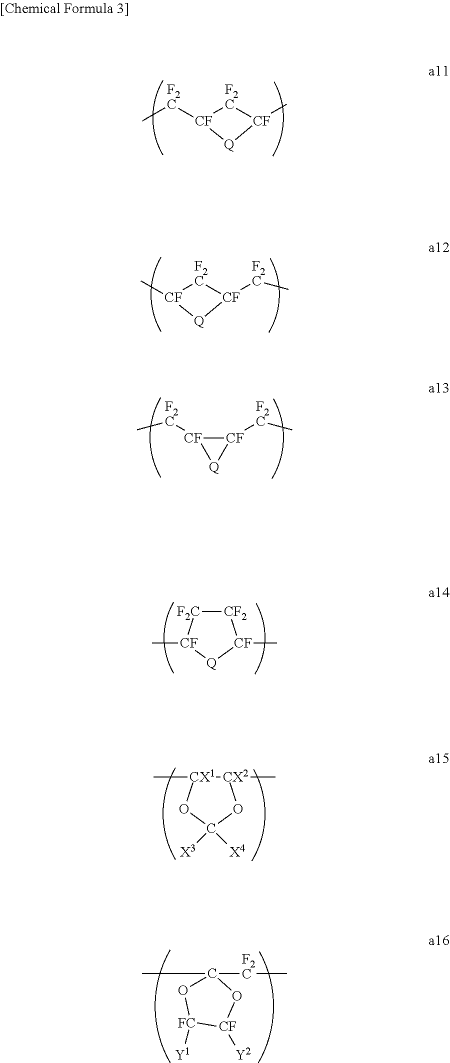

As the unit A, a unit formed by cyclopolymerization of a diene-based fluorine-containing polymer is preferred from the viewpoint of excellent chemical stability.

One or two or more types of the units A may be comprised in the present polymer.

### <Unit B>

The unit B is a unit based on a fluorine-containing monomer b having an adhesive functional group.

The unit B contributes to adhesion and adhesion stability.

When the adhesive functional group is present only at the end of the main chain of the polymer, although the adhesion is excellent, the adhesion stability is poor. It is thought that the inclusion of unit B in the present polymer shortens the distance between adhesive functional groups in the molecule and improves the adhesion stability.

Examples of the adhesive functional group include a hydroxyl group, a carboxy group, an ester thereof, a sulfo group, an amino group, and an amide group.

The adhesive functional group is preferably at least one selected from the group consisting of a hydroxyl group, a carboxy group, an ester thereof, a sulfo group, and an amino group, and is particularly preferably a hydroxyl group, from the viewpoint of excellent metal adhesion.

As the fluorine-containing monomer b, a fluorine-containing monomer b1 is preferred from the viewpoint of excellent polymerization reactivity.

CX^{a}X^{b}═CX^{c}—R¹—Z Formula b1

In the formula b1, each of X^{a}, X^{b} and X^{c} independently represents a fluorine atom or a chlorine atom, and at least one of X^{a}, X^{b} and X^{c} is a fluorine atom. R¹ is a divalent perfluoroorganic group which may have at least one hetero atom selected from the group consisting of an oxygen atom and a sulfur atom. Z is CₐH₂ₐOH, COOH, COOR², SO₃H, C_{b}H_{2b}NH₂ or C_{d}H_{2d}CO₂NH₂, a is an integer from 0 to 6, R² is an alkyl group having 1 to 12 carbon atoms, b is an integer from 0 to 6 and d is an integer from 0 to 6.

Examples of CX^{a}X^{b}═CX^{c}— include CF₂═CF— and CF₂═CCl—. Among these, CF₂═CF— is preferred from the viewpoint of excellent copolymerization reactivity with the monomer forming the unit A.

Examples of R¹ include a perfluoroalkylene group, a perfluoroalkylene group having an oxygen atom (—O—) or a sulfur atom (—S—) at the end on the CX^{a}X^{b}═CX^{c} side of the perfluoroalkylene group, or a group in which two or more perfluoroalkylene groups are connected via an oxygen atom or a sulfur atom. The perfluoroalkylene group may be linear or branched. The number of carbon atoms in the perfluoroalkylene group is preferably 14 or less, more preferably 10 or less, and particularly preferably 4 or less.

In Z, when a in CₐH₂ₐOH is 0, OH in CₐH₂ₐOH and R¹ are directly bonded. a is preferably an integer of 1 or more from the viewpoint of easy availability of the monomer, and is preferably an integer of 4 or less from the viewpoint of excellent solubility in fluorine-based solvents.

When a is 2 or more, CₐH₂ₐOH may be linear or branched, but is preferably linear.

In COOR², R² may be linear or branched. R² is preferably an alkyl group having 1 to 10 carbon atoms, and particularly preferably a methyl group.

When b in C_{b}H_{2b}NH₂ is 0, NH₂ in C_{b}H_{2b}NH₂ and R¹ are directly bonded. b is preferably an integer of 1 or more from the viewpoint of easy availability of the monomer, and is preferably an integer of 4 or less from the viewpoint of excellent solubility in fluorine-based solvents.

When b is 2 or more, C_{b}H_{2b}NH₂ may be linear or branched, but is preferably linear.

When d in C_{d}H_{2d}CO₂NH₂ is 0, CO₂NH₂ in C_{d}H_{2d}CO₂NH₂ and R¹ are directly bonded. d is preferably an integer of 1 or more from the viewpoint of easy availability of the monomer, and is preferably an integer of 4 or less from the viewpoint of excellent solubility in fluorine-based solvents.

Z is preferably CₐH₂ₐOH from the viewpoint of excellent copolymerization reactivity with the monomer forming the unit A.

As the fluorine-containing monomer b1, a fluorine-containing monomer b1-1 is particularly preferred from the viewpoint of excellent polymerization reactivity.

CX^{a}X^{b}═CX^{c}—CₑF₂ₑ—Y^{b}—C_{f}F_{2f}—Z Formula b1-1

In the Formula b1-1, X^{a}, Xb, Xc and Z are respectively as defined for X^{a}, X^{b}, X^{c} and Z in the Formula b1, e is an integer from 0 to 4, Y^{b} is an oxygen atom or a sulfur atom, and f is an integer from 2 to 10.

When e is 0, the carbon atom to which X^{c} is bonded and Y^{b} are directly bonded. When e is 2 or more, CₑF₂ₑ may be linear or branched, but is preferably linear. e is preferably 0 or 1, and particularly preferably 0.

C_{f}F_{2f} may be linear or branched, but is preferably linear. f is preferably an integer of 10 or less, and particularly preferably an integer of 4 or less.

e+f is preferably an integer of 10 or less, and particularly preferably an integer of 4 or less.

Examples of the fluorine-containing monomer b1 include the following compounds.
CF₂═CF—CF₂—Z,
CF₂═CF—(CF₂)₂—Z,
CF₂═CF—O—(CF₂)₂—Z,
CF₂═CF—O—(CF₂)₃—Z,
CF₂═CF—O—(CF₂)₄—Z,
CF₂═CF—O—CF₂CF(CF₃)O(CF₂)₂—Z,
CF₂═CF—O—CF₂CF(CF₃)O(CF₂)₃—Z,
CF₂═CF—O—(CF₂)₃₀(CF₂)₂—Z,
CF₂═CF—O—(CF₂)₂O(CF₂)₂—Z,
CF₂═CF—CF₂—O—CF(CF₃)—Z,
CF₂═CF—CF₂—O—CF(CF₃)CF₂OCF(CF₃)—Z.

One or two or more types of the units B may be comprised in the present polymer.

### <Unit C>

The unit C is a unit based on a fluorine-containing monomer c described below. The fluorine-containing monomer c is a fluorine-containing monomer that has at least one hetero atom selected from the group consisting of an oxygen atom and a sulfur atom, but does not have a fluorine-containing aliphatic ring structure constituting the main chain, and an adhesive functional group.

When the present polymer comprises the unit C, the water and oil repellency tends to be further improved.

The fluorine-containing monomer c preferably has a perfluoroalkyl group from the viewpoint of excellent water and oil repellency. The perfluoroalkyl group may be linear or branched. The number of carbon atoms in the perfluoroalkyl group is preferably 10 or less, and more preferably 4 or less from the viewpoint of easy availability.

The fluorine-containing monomer c is preferably a perfluoromonomer.

As the fluorine-containing monomer c, a fluorine-containing monomer c1 is preferred from the viewpoint of excellent water and oil repellency.

CX^{d}X^{e}═CX^{f}—C_{c}F_{2c}—Y^{c}—R^{F} Formula c1

In the Formula c1, each of X^{d}, X^{e} and X^{f} independently represents a fluorine atom or a chlorine atom, and at least one of X^{d}, X^{e} and X^{f} is a fluorine atom. c is an integer from 0 to 4, and Y^{c} is an oxygen atom or a sulfur atom. R^{F} is a perfluoroalkyl group having 1 to 10 carbon atoms.

Examples of CX^{d}X^{e}═CX^{f}— include the same as the above-mentioned CX^{a}X^{b}═CX^{c}—.

When c is 0, the carbon atom to which X^{f} is bonded and Y^{c} are directly bonded. c is preferably 0 or 1.

The perfluoroalkyl group represented by R^{F} is the same as described above.

Examples of the fluorine-containing monomer c1 include perfluoro(methyl vinyl ether), perfluoro(ethyl vinyl ether), perfluoro(propyl vinyl ether), perfluoro(butyl vinyl ether), and perfluoro(pentyl ether).

When the present polymer further comprises the unit C, one or two or more types of the units C may be comprised.

The unit D is another unit other than the unit A, the unit B, and the unit C.

The unit D is not particularly limited as long as it is based on a monomer copolymerizable with both the monomer forming the unit A and the monomer forming the unit B. Examples thereof include a unit based on a fluorine-containing olefin such as tetrafluoroethylene, and vinylidene chloride.

When the present polymer further comprises the unit D, one or two or more types of the units D may be comprised.

The unit D is preferably a perfluoro unit.

In the present polymer, with respect to all units constituting the present polymer, the content of the unit B is preferably 0.1% by mass or more, more preferably 0.2% by mass or more, particularly preferably 0.5% by mass or more, and is preferably 20% by mass or less, more preferably 10% by mass or less, and particularly preferably 8% by mass or less. When the content of the unit B is equal to or more than the above lower limit value, the adhesion and adhesion stability of the coating film are further improved. When the content of the unit B is equal to or less than the above upper limit value, the flexibility and moisture-proof properties of the coating film are further improved.

With respect to all units constituting the present polymer, the total content of the unit A and the unit C is preferably 10% by mass or more, more preferably 20% by mass or more, still more preferably 40% by mass or more, particularly preferably 80% by mass or more, and is preferably 99.9% by mass or less, more preferably 99.8% by mass or less, and particularly preferably 99.5% by mass or less. When the total content of the unit A and the unit C is equal to or more than the above lower limit value, the flexibility and moisture-proof properties of the coating film are further improved. When the total content of the unit A and the unit C is equal to or less than the above upper limit value, the adhesion and adhesion stability of the coating film are further improved.

When the present polymer does not comprise the unit C, the total content of the unit A and the unit C is the content of the unit A.

When the present polymer comprises the unit C, a mass ratio expressed by the formula: (unit A)/(unit C) is preferably from 25/75 to 80/20, more preferably from 35/65 to 80/20, and particularly preferably from 50/50 to 80/20. When the (unit A)/(unit C) ratio is equal to or more than the above lower limit value, the moisture-proof properties of the coating film is further improved. When the (unit A)/(unit C) ratio is equal to or less than the above upper limit value, the water and oil repellency of the coating film is further improved.

When the present polymer comprises the unit A and the unit B but no unit C, with respect to all units constituting the present polymer, it is preferable that the unit A is from 80 to 99.5% by mass and the unit B is from 0.5 to 20% by mass, and it is more preferable that the unit A is from 90 to 99% by mass and the unit B is from 1 to 10% by mass. The total content of the unit A and the unit B is preferably 80.5% by mass or more, more preferably 91% by mass or more, and may be 100% by mass, with respect to all units constituting the present polymer.

When the present polymer comprises the unit A, the unit B, and the unit C, with respect to all units constituting the present polymer, it is preferable that the unit A is from 10 to 75% by mass, the unit B is from 0.5 to 15% by mass and the unit C is from 10 to 75% by mass, and it is more preferable that the unit A is from 34.5 to 75% by mass, the unit B is from 0.5 to 10% by mass and the unit C is from 15 to 65% by mass. The total content of the unit A, the unit B, and the unit C is preferably 20.5% by mass or more, more preferably 50% by mass or more, and may be 100% by mass, with respect to all units constituting the present polymer.

The mass average molecular weight (Mw) of the present polymer is preferably from 10,000 to 30,000, and more preferably from 30,000 to 100,000. When Mw is equal to or more than the above lower limit value, the fluorine-containing polymer is less likely to become brittle. When Mw is equal to or less than the above upper limit value, the solubility in a liquid medium and moldability are further improved.

### (Method for Producing Polymer)

The present polymer can be obtained, for example, by polymerizing a monomer component comprising a fluorine-containing monomer forming the unit A and the fluorine-containing monomer b.

The monomer component may further comprise a fluorine-containing monomer c, if necessary.

The monomer component may further comprise a monomer that forms the unit D, if necessary.

The fluorine-containing monomer forming the unit A, the fluorine-containing monomer b, the fluorine-containing monomer c, and the monomer forming the unit D can each be produced by a known production method. If available, commercially available products can be used as monomers.

The content of each monomer with respect to the entire monomer component is set in accordance with the content of each unit with respect to all units constituting the present polymer.

The polymerization of the monomer components is preferably carried out in the presence of a polymerization initiator. If necessary, a chain transfer agent, an emulsifier, a dispersion stabilizer, and the like may also be present.

Examples of the polymerization method include various polymerization methods such as a solution polymerization method, a suspension polymerization method, an emulsion polymerization method, and a bulk polymerization method. The polymerization temperature is, for example, from 20 to 80° C.

After polymerization, the terminal group of the produced fluorine-containing polymer may be converted into an adhesive functional group (such as a carboxylic acid fluoride group and a carboxy group), if necessary. Examples of the conversion method include the method described in Japanese Unexamined Patent Application, First Publication No. 2006-257329 and the method described in International Patent Publication No. 2014/156996.

There are no particular limitations on the applications of the present polymer, and examples thereof include a moisture-proof coating agent and a buffer coating agent.

Among the above, the present polymer is suitable as a moisture-proof coating agent.

The moisture-proof coating agent is applied to printed boards such as printed wiring boards and printed circuit boards, and various electronic circuit components in order to prevent corrosion of wiring metals in electronic components, an increase in leakage current, and the like caused by moisture and dust, and to ensure the long-term reliability of electronic components. Examples of the printed boards and electronic circuit components include hybrid ICs, chips on boards, chips on glass, tape automated bonding, flip chips, chip size packages, and various other multichip modules.

### (Composition)

A composition according to one embodiment of the present invention (hereinafter also referred to as “the present composition”) comprises the present polymer and a liquid medium.

The present composition may further comprises other components other than the present polymer and the liquid medium, as necessary, within a range that does not impair the effects of the present invention.

Examples of the liquid medium include a protic solvent and an aprotic solvent. A “protic solvent” is a solvent that has proton donating properties. An “aprotic solvent” is a solvent that does not have proton donating properties.

The liquid medium is preferably one that dissolves at least the present polymer. As the liquid medium, a fluorine-containing solvent is preferred.

Examples of the protic fluorine-containing solvent include those shown below.

Fluorine-containing alcohols such as trifluoroethanol, 2,2,3,3,3-pentafluoro-1-propanol, 2-(perfluorobutyl)ethanol, 2-(perfluorohexyl)ethanol, 2-(perfluorooctyl)ethanol, 2-(perfluorodecyl)ethanol, 2-(perfluoro-3-methylbutyl)ethanol, 2,2,3,3-tetrafluoro-1-propanol, 2,2,3,3,4,4,5,5-octafluoro-1-pentanol, 2,2,3,3,4,4,5,5,6,6,7,7-dodecafluoro-1-heptanol, 2,2,3,3,4,4,5,5,6,6,7,7,8,8-hexadecafluoro-1-nonanol, 1,1,1,3,3,3-hexafluoro-2-propanol, and 1,3,3,4,4,4-hexafluoro-2-butanol; fluorine-containing carboxylic acids such as trifluoroacetic acid, perfluoropropanoic acid, perfluorobutanoic acid, perfluoropentanoic acid, perfluorohexanoic acid, perfluoroheptanoic acid, perfluorooctanoic acid, perfluorononanoic acid, perfluorodecanoic acid, 1,1,2,2-tetrafluoropropanoic acid, 1,1,2,2,3,3,4,4-octafluoropentanoic acid, 1,1,2,2,3,3,4,4,5,5-dodecafluoroheptanoic acid, and 1,1,2,2,3,3,4,4,5,5,6,6-hexadecafluorononanoic acid; fluorine-containing sulfonic acids such as trifluoromethanesulfonic acid and heptadecafluorooctanesulfonic acid; and the like.

Examples of the aprotic fluorine-containing solvent include those shown below.

Polyfluoroaromatic compounds such as 1,4-bis(trifluoromethyl)benzene, polyfluorotrialkylamine compounds such as perfluorotributylamine, polyfluorocycloalkane compounds such as perfluorodecalin, polyfluorocyclic ether compounds such as perfluoro(2-butyltetrahydrofuran), perfluoropolyethers, polyfluoroalkane compounds, hydrofluoroethers (HFE), and the like.

Examples of HFE include CF₃CH₂OCF₂CF₂H (AE-3000 (product name), manufactured by AGC Inc.), C₄F₉OCH₃ (Novec-7100 (product name), manufactured by 3M Company), C₄F₉OC₂H₅(Novec-7200 (product name), manufactured by 3M Company), and C₂F₅CF(OCH₃)C₃F₇(Novec-7300 (product name), manufactured by 3M Company).

One type of these liquid media may be used alone or two or more types thereof may be used in combination. Further, in addition to these, a wide range of compounds can be used as the liquid medium.

As the liquid medium, an aprotic fluorine-containing solvent is preferred since it is a good solvent for the present polymer. An aprotic fluorine-containing solvent and a protic non-fluorine solvent (such as methanol) may be used in combination. When used in combination, the protic non-fluorine solvent is preferably comprised in an amount of 1 to 20% by mass with respect to the total solvent.

The boiling point of the liquid medium is preferably from 65 to 220° C., and particularly preferably from 70 to 220° C., because the formation of a uniform coating film is facilitated when the present composition is applied.

The content of the present polymer in the present composition is preferably 3% by mass or more, more preferably 5% by mass or more, and may be 100% by mass, with respect to the total solid content of the present composition. When the content of the present polymer is equal to or more than the above lower limit value, the adhesion of the coating film to the base material is further improved.

The solid content is the sum of all components excluding the liquid medium.

The content of the liquid medium is set in accordance with the solid content concentration of the present composition.

The solid content concentration of the present composition may be appropriately set depending on the coating method of the present composition, the thickness of the coating film to be formed, and the like, and is, for example, from 0.1 to 10% by mass with respect to the present composition as a whole.

The present composition can be obtained, for example, by mixing the present polymer, a liquid medium, and other components as necessary. In the method for producing a polymer described above, when the monomer components are polymerized in the presence of a liquid medium (such as a solvent or a dispersion medium), the obtained reaction solution can be used as it is as the present composition. The present composition may be obtained by partially or entirely replacing the liquid medium of this reaction solution and adding other components as necessary.

There are no particular limitations on the applications of the present composition, and examples thereof include a moisture-proof coating agent and a buffer coating agent.

Among the above, the present composition is suitable as a moisture-proof coating agent.

### (Article)

An article according to one embodiment of the present invention (hereinafter also referred to as “the present article”) has a coating film of the present composition on a base material. The present article comprises a base material and a coating film of the present composition provided on the surface of the base material.

The thickness of the coating film of the present composition is preferably from 1 to 100 μm, and more preferably from 1 to 50 μm. When the thickness of the coating film is equal to or more than the above lower limit value, the moisture-proof properties, water and oil repellency, and heat resistance of the coating film are further improved. When the thickness of the coating film is equal to or less than the above upper limit value, the adhesion, flexibility, and cracking resistance of the coating film are further improved.

There are no particular restrictions on the base material, and examples thereof include glass base materials; metal base materials such as silicon, stainless steel (SUS), aluminum, copper, and alloys thereof, plastic base materials such as polyimide and imide; and base materials composed of multiple layers obtained by laminating one or more metal films or films on the above-described base materials.

The shape of the base material is also not particularly limited, and examples thereof include various shapes such as sheet, chip, film, fiber, spherical, and polygonal shapes. The base material may be a substrate patterned with wiring or the like, a chip, or a semiconductor device.

The base material is preferably a printed board such as a printed wiring board and a printed circuit board.

Since the coating film of the present composition exhibits excellent adhesion, moisture-proof properties, and water and oil repellency, by covering the wiring of printed boards, electronic components, and the like with the coating film of the present composition, corrosion of wiring metals in electronic components, an increase in leakage current, and the like caused by moisture and dust can be prevented, and the long-term reliability of electronic components is improved.

The present article can be obtained by coating the present composition onto a base material, followed by drying.

There are no particular restrictions on the coating method, and known wet coating methods and casting methods can be applied.

The drying is not limited as long as the liquid medium can be removed, and may be drying with or without heating. The drying temperature is preferably from 20 to 40° C., and more preferably from 30 to 40° C.

### EXAMPLES

Hereinafter, the present invention will be described in more detail with reference to Examples and Comparative Examples, but the present invention is not limited to the following Examples as long as it does not exceed the scope and spirit thereof.

Examples 1 to 10 are Examples of the present invention, and Examples 11 to 16 are Comparative Examples.

### EXPLANATION OF ABBREVIATIONS

MOL: 2,2,3,3,4,4-hexafluoro-4-[(1,2,2-trifluoroethenyl)oxy]-1-butanol.
BVE: perfluorobutenyl vinyl ether.
PPVE: perfluoropropyl vinyl ether.
IPP-10AC: 10% solution of diisopropyl peroxydicarbonate (“Peroyl IPP” (product name), manufactured by NOF Corporation) in 1H-perfluorohexane (“AC-2000” (product name), manufactured by AGC Inc.).

### (Evaluation Method)

### <Content of Each Unit in Fluorine-Containing Polymer>

The content of each unit in the fluorine-containing polymer was calculated based on the measurement results of ¹H-NMR and ¹⁹F-NMR using a nuclear magnetic resonance apparatus (“AVANCE NEO400” (device name), manufactured by Bruker Corporation).

A measurement sample was prepared by dissolving a fluorine-containing polymer whose mass had been measured in advance and 1,4-bis(trifluoromethyl)benzene in perfluorobenzene, and ¹H-NMR and ¹⁹F-NMR were measured.

The content of the MOL unit in the fluorine-containing polymer obtained in each Synthesis Example described below was obtained by determining an integral ratio of the peak attributed to the hydrogen atom of the methylene group of the MOL unit in the fluorine-containing polymer and the peak attributed to the hydrogen atom of the aromatic ring of 1,4-bis(trifluoromethyl)benzene, followed by conversion into a mass ratio.

The content of the PPVE unit in the fluorine-containing polymer obtained in each Synthesis Example described below was obtained by determining an integral ratio of the peak attributed to the fluorine atom of the trifluoromethyl group of the PPVE unit in the fluorine-containing polymer and the peak attributed to the fluorine atom of 1,4-bis(trifluoromethyl)benzene, followed by conversion into a mass ratio.

The content of the BVE unit in the fluorine-containing polymer obtained in each Synthesis Example described below, which was a ternary fluorine-containing polymer containing only the MOL unit, the PPVE unit, and the BVE unit, was calculated as a value obtained by subtracting the contents of the above-mentioned MOL unit and the PPVE unit from 100.

### <Mass Average Molecular Weight of Fluorine-Containing Polymer>

The mass average molecular weight of a fluorine-containing polymer was measured using a gel permeation chromatograph (GPC). Using dichloropentafluoropropane as a solvent, a value equivalent to the standard PMMA was measured.

### <Adhesion of Coating Film to Copper Plate>

The composition obtained in each example was applied onto a copper plate using a bar coater (“Bar Coater 200 mm” (product name), manufactured by Allgood Corporation) and dried at 25° C. for 24 hours to form a coating film with a thickness of 10 m. A cross-cut test was conducted on the copper plate on which the coating film was formed in accordance with JIS K 5600-5-6. More specifically, a grid pattern was created on the coating film using a cutter, and cellophane tape was stuck thereon and then peeled off to determine the value of surface delamination, which was classified in accordance with the following criteria. The term “surface delamination” refers to a ratio of the area of the coating film remaining on the substrate after the cross-cut test with respect to the total area of the coating film before the cross-cut test.
Class 0: surface delamination is less than 1%.
Class 1: surface delamination is 1% or more and less than 5%.
Class 2: surface delamination is 5% or more and less than 15%.
Class 3: surface delamination is 15% or more and less than 35%.
Class 4: surface delamination is 35% or more and less than 100%.
Class 5: surface delamination is 100%.

From the results of the above classification, adhesion was determined based on the following criteria.
S: Class 0 or Class 1.
A: Class 2.
B: Class 3.
C: Class 4 or Class 5.

Two more copper plates on which a coating film was formed were produced under the same conditions as described above, a cross-cut test was conducted on each plate, and the surface delamination values were classified. From the results of a total of three cross-cut tests, the adhesion stability was evaluated based on the following criteria. However, those that were classified as 5 in all three cross-cut tests were excluded from the evaluation of adhesion stability.
A: The classification results are the same in all three cross-cut tests.
C: At least one classification result is different from others in a total of three cross-cut tests.

### <Adhesion of Coating Film to Resist Plate>

The same evaluation as the above evaluation for copper plate adhesion was performed with the exception that a resist plate was used instead of the copper plate.

### <Flexibility of Coating Film>

The composition obtained in each example was applied onto a copper plate using a bar coater (“Bar Coater 200 mm” (product name), manufactured by Allgood Corporation) and dried overnight at room temperature to form a coating film with a thickness of 10 μm.

A mandrel test was conducted using a copper plate on which a coating film of the composition was formed as a test plate in accordance with JIS K 5600-5-1. More specifically, the test plate was sandwiched and fixed using a main body clamp in a tester combined with a mandrel (“Cylindrical mandrel bend tester” (product name), manufactured by Allgood Corporation). The roller was brought close to the test plate, and the handle was evenly rotated by 180° over a period of 1 to 2 seconds. Thereafter, cracks in the coating film and peeling of the coating film from the base were inspected. The mandrels were changed to smaller ones until the coating film cracked or peeled, and the diameter of the mandrel at which cracking or peeling occurred for the first time was recorded. From this value, the flexibility of the coating film was evaluated based on the following criteria.
A: The diameter of the mandrel at which cracking or peeling occurred for the first time is less than 2 mm.
B: The diameter of the mandrel at which cracking or peeling occurred for the first time is 2 mm or more and less than 8 mm.
C: The diameter of the mandrel at which cracking or peeling occurred for the first time was 10 mm or more.

### <Water and Oil Repellency of Coating Film>

The composition was applied onto a glass substrate by spin coating and dried by heating at 80° C. for 10 minutes to form a coating film with a thickness of 10 μm. Approximately 1 μL of water or n-hexadecane was dropped onto this coating film, and the contact angle was measured using a contact angle meter (“SA-301” manufactured by Kyowa Interface Science Co., Ltd.).

### <Moisture-Proof Properties of Coating Film>

The composition obtained in each example was applied onto a nylon film using a bar coater (“Bar Coater 200 mm” (product name), manufactured by Allgood Corporation) and dried overnight at room temperature to form a coating film with a thickness of 10 μm.

A cup test was conducted using a nylon film on which a coating film of the composition was formed as a test film in accordance with JIS Z0208. More specifically, anhydrous calcium chloride was placed as a moisture absorbent in a moisture permeable cup made of an aluminum material satisfying a permeation area of 2.826×10⁻³ m² (60 mmφ). The opening of the moisture permeable cup was covered with the test film, and the moisture permeable cup was sealed with an O-ring and a sealant. This was left to stand for 96 hours in a constant temperature and humidity chamber (“ARS-1100-J” (product name), manufactured by ESPEC Corp.) set at a temperature of 40° C. and a relative humidity of 90%. The weighing operation was repeated every 24 hours, and an increase in mass of the test specimen was recorded. The reference value was subtracted from the value of mass increase to calculate the water vapor permeability [g/(m²·24 h)] of the fluorine-containing polymer, and the moisture-proof properties of the coating film were evaluated from that value based on the following criteria.
S: water vapor permeability is less than 4.0.
A: water vapor permeability is 4.0 or more and less than 7.0.
B: water vapor permeability is 7.0 or more and less than 10.0.
C: water vapor permeability is 10.0 or more.

### Synthesis Example 1

A pressure-resistant glass reactor with an internal volume of 100 mL was charged with 39.0 g of BVE, 1.0 g of MOL, and 3.1 g of IPP-10AC, a magnetic stirring bar was placed in advance, and then the liquid phase was frozen and degassed. Nitrogen gas was filled until the internal pressure of the reactor reached 0.05 MPaG, and the internal temperature was raised to 40° C. The resulting mixture was stirred at a speed of 300 rpm for 6 hours while maintaining the internal temperature. After purging the nitrogen gas in the gas phase, the reactor was opened to obtain a viscous liquid. The solid content of this viscous liquid was coagulated with 1,1,2,2-tetrafluoroethyl-2,2,2-trifluoroethyl ether (“AE-3000” (product name), manufactured by AGC Inc.). The coagulated solid content was collected and redissolved in 1,1,1,2,2,3,4,5,5,5-decafluoro-3-methoxy-4-(trifluoromethyl)pentane (“Novec-7300” (product name), manufactured by 3M Company), and then the solid content was coagulated again with AE-3000. The obtained solid content was vacuum dried at 50° C. to obtain 8.8 g of a white fluorine-containing polymer 1. The letter “G” in “0.05 MPaG” indicates gauge pressure (the same applies hereinafter).

The content ratio of each monomer in the obtained fluorine-containing polymer 1 was BVE/MOL=99/1 (mass ratio) and 99/1 (molar ratio). Since this polymer did not dissolve in dichloropentafluoropropane, the mass average molecular weight was not determined.

### Synthesis Example 2

A pressure-resistant glass reactor with an internal volume of 100 mL was charged with 37.0 g of BVE, 3.0 g of MOL, and 3.1 g of IPP-10AC, a magnetic stirring bar was placed in advance, and then the liquid phase was frozen and degassed. Nitrogen gas was filled until the internal pressure of the reactor reached 0.05 MPaG, and the internal temperature was raised to 40° C. The resulting mixture was stirred at a speed of 300 rpm for 24 hours while maintaining the internal temperature. After purging the nitrogen gas in the gas phase, the reactor was opened to obtain a viscous liquid. The solid content of this viscous liquid was coagulated with AE-3000. The coagulated solid content was collected and redissolved in Novec-7300, and then the solid content was coagulated again with AE-3000. The obtained solid content was vacuum dried at 50° C. to obtain 11.7 g of a white fluorine-containing polymer 2.

The content ratio of each monomer in the obtained fluorine-containing polymer 2 was BVE/MOL=95/5 (mass ratio) and 95/5 (molar ratio). Since this polymer did not dissolve in dichloropentafluoropropane, the mass average molecular weight was not determined.

### Synthesis Example 3

10.4 g of a white fluorine-containing polymer 3 was obtained in the same manner as Synthesis Example 2 with the exception that 34.0 g of BVE and 6.0 g of MOL were used.

The content ratio of each monomer in the obtained fluorine-containing polymer 3 was BVE/MOL=90/10 (mass ratio) and 90/10 (molar ratio). Since this polymer did not dissolve in dichloropentafluoropropane, the mass average molecular weight was not determined.

### Synthesis Example 4

A pressure-resistant glass reactor with an internal volume of 100 mL was charged with 11.4 g of BVE, 27.4 g of PPVE, 1.2 g of MOL, and 3.1 g of IPP-10AC, a magnetic stirring bar was placed in advance, and then the liquid phase was frozen and degassed. Nitrogen gas was filled until the internal pressure of the reactor reached 0.05 MPaG, and the internal temperature was raised to 30° C. The resulting mixture was stirred at a speed of 300 rpm for 96 hours while maintaining the internal temperature. After purging the nitrogen gas in the gas phase, the reactor was opened to obtain a viscous liquid. The solid content of this viscous liquid was coagulated with AE-3000. The coagulated solid content was collected and redissolved in a mixed solution of ethyl nonafluoroisobutyl ether and ethyl nonafluorobutyl ether (“Novec-7200” (product name), manufactured by 3M Company), and then the solid content was coagulated again with AE-3000. The obtained solid content was vacuum dried at 50° C. to obtain 4.8 g of a white fluorine-containing polymer 4.

The content ratio of each monomer in the obtained fluorine-containing polymer 4 was BVE/PPVE/MOL=39/60/1 (mass ratio) and 38/61/1 (molar ratio). The mass average molecular weight of this polymer was 14,000.

### Synthesis Example 5

6.1 g of a white fluorine-containing polymer 5 was obtained in the same manner as Synthesis Example 4 with the exception that 19.4 g of BVE, 19.4 g of PPVE, and 1.2 g of MOL were used.

The content ratio of each monomer in the obtained fluorine-containing polymer 5 was BVE/PPVE/MOL=54/45/1 (mass ratio) and 53/46/1 (molar ratio). The mass average molecular weight of this polymer was 20,000.

### Synthesis Example 6

11.2 g of a white fluorine-containing polymer 6 was obtained in the same manner as Synthesis Example 4 with the exception that 28.0 g of BVE, 11.6 g of PPVE, and 0.4 g of MOL were used.

The content ratio of each monomer in the obtained fluorine-containing polymer 6 was BVE/PPVE/MOL=69/30/1 (mass ratio) and 68/31/1 (molar ratio). The mass average molecular weight of this polymer was 38,000.

### Synthesis Example 7

10.7 g of a white fluorine-containing polymer 7 was obtained in the same manner as Synthesis Example 4 with the exception that 28.0 g of BVE, 8.0 g of PPVE, and 4.0 g of MOL were used.

The content ratio of each monomer in the obtained fluorine-containing polymer 7 was BVE/PPVE/MOL=70/25/5 (mass ratio) and 71/24/5 (molar ratio). The mass average molecular weight of this polymer was 20,000.

### Synthesis Example 8

13.3 g of a white fluorine-containing polymer 8 was obtained in the same manner as Synthesis Example 4 with the exception that 24.0 g of BVE, 12.0 g of PPVE, and 4.0 g of MOL were used.

The content ratio of each monomer in the obtained fluorine-containing polymer 8 was BVE/PPVE/MOL=66/29/5 (mass ratio) and 67/28/5 (molar ratio). The mass average molecular weight of this polymer was 18,000.

### Synthesis Example 9

10.9 g of a white fluorine-containing polymer 9 was obtained in the same manner as Synthesis Example 4 with the exception that 22.0 g of BVE, 12.0 g of PPVE, and 6.0 g of MOL were used.

The content ratio of each monomer in the obtained fluorine-containing polymer 9 was BVE/PPVE/MOL=63/27/10 (mass ratio) and 64/26/10 (molar ratio). The mass average molecular weight of this polymer was 18,000.

### Synthesis Example 10

15.6 g of a white fluorine-containing polymer 10 was obtained in the same manner as Synthesis Example 4 with the exception that 24.0 g of BVE, 10.0 g of PPVE, and 6.0 g of MOL were used.

The content ratio of each monomer in the obtained fluorine-containing polymer 10 was BVE/PPVE/MOL=70/20/10 (mass ratio) and 71/19/10 (molar ratio). The mass average molecular weight of this polymer was 16,000.

### Synthesis Example 11

A pressure-resistant glass reactor with an internal volume of 100 mL was charged with 12.0 g of BVE, 28.0 g of PPVE, and 3.1 g of IPP-10AC, a magnetic stirring bar was placed in advance, and then the liquid phase was frozen and degassed. Nitrogen gas was filled until the internal pressure of the reactor reached 0.05 MPaG, and the internal temperature was raised to 30° C. The resulting mixture was stirred at a speed of 300 rpm for 96 hours while maintaining the internal temperature. After purging the nitrogen gas in the gas phase, the reactor was opened to obtain a viscous liquid. The solid content of this viscous liquid was coagulated with AE-3000. The coagulated solid content was collected and redissolved in a mixed solution of ethyl nonafluoroisobutyl ether and ethyl nonafluorobutyl ether (“Novec-7200” (product name), manufactured by 3M Company), and then the solid content was coagulated again with AE-3000. The obtained solid content was vacuum dried at 50° C. to obtain 5.1 g of a white fluorine-containing polymer 11.

The content ratio of each monomer in the obtained fluorine-containing polymer 11 was BVE/PPVE=42/58 (mass ratio) and 41/59 (molar ratio). The mass average molecular weight of this polymer was 16,000.

### Synthesis Example 12

10.4 g of a white fluorine-containing polymer 12 was obtained in the same manner as Synthesis Example 11 with the exception that 20.0 g of BVE and 20.0 g of PPVE were used.

The content ratio of each monomer in the obtained fluorine-containing polymer 12 was BVE/PPVE=56/44 (mass ratio) and 55/45 (molar ratio). The mass average molecular weight of this polymer was 24,000.

### Synthesis Example 13

21.7 g of a white fluorine-containing polymer 13 was obtained in the same manner as Synthesis Example 11 with the exception that 28.0 g of BVE and 12.0 g of PPVE were used.

The content ratio of each monomer in the obtained fluorine-containing polymer 13 was BVE/PPVE=70/30 (mass ratio) and 69/31 (molar ratio). The mass average molecular weight of this polymer was 37,000.

### Synthesis Example 14

A pressure-resistant glass reactor with an internal volume of 100 mL was charged with 40.0 g of BVE, 40.0 g of Novec-7300 as a solvent, 1.0 g of methanol as a chain transfer agent, and 3.1 g of IPP-10AC as a polymerization initiator, a magnetic stirring bar was placed in advance, and then the liquid phase was frozen and degassed. Nitrogen gas was filled until the internal pressure of the reactor reached 0.05 MPaG, and the internal temperature was raised to 40° C. The resulting mixture was stirred at a speed of 300 rpm for 48 hours while maintaining the internal temperature. After purging the nitrogen gas in the gas phase, the reactor was opened to obtain a viscous liquid. Methanol was added to this viscous liquid to coagulate the solid content. The solid content was vacuum dried at 50° C. to obtain 22.5 g of a white fluorine-containing polymer 14. Since this polymer did not dissolve in dichloropentafluoropropane, the mass average molecular weight was not determined.

### Synthesis Example 15

A terminal group of the fluorine-containing polymer 14 due to the polymerization initiator or chain transfer agent was converted into an end having an acid group by the method described in Japanese Unexamined Patent Application, First Publication No. JP.H04-189880. More specifically, the fluorine-containing polymer 14 was subjected to a heat treatment in air at 300° C. for 8 hours and then immersed in water to obtain a fluorine-containing polymer 15 having an acid group at the end.

### Examples 1 to 16

Compositions 1 to 16 were prepared by dissolving the fluorine-containing polymers 1 to 13 and 15 in fluorine-based solvents shown in Table 1, respectively. The fluorine-containing polymer did not completely dissolve in the fluorine-based solvent at times when the number of MOL units therein increased. In this case, methanol (MeOH) was appropriately mixed at a ratio shown in Table 1 to dissolve this polymer. For Compositions 14 to 16, perfluoropolyether (PFPE) described in “Example 1” in Japanese Unexamined Patent Application, First Publication No. 2006-257329 was added so as to achieve a mass ratio shown in Table 1. With respect to the total mass of each composition, the total amount of the fluorine-containing polymer and PFPE was 5% by mass, and the amount of the liquid medium was 95% by mass.

TABLE 1

| | | Liquid medium | | | |
|---|---|---|---|---|---|
| | Fluorine- | | Fluorine-based | | Fluorine-containing |
| | containing | | solvent/MeOH (mass | PFPE | polymer/PFPE |
| Example | polymer | Type | ratio) | addition | (mass ratio) |
| 1 | 1 | Novec-7300/ | 100/0 | Absent | 100/0 |
| 2 | 2 | MeOH | 95/5 | | 100/0 |
| 3 | 3 | | 90/10 | | 100/0 |
| 4 | 4 | Novec-7200 | 100/0 | | 100/0 |
| 5 | 5 | | 100/0 | | 100/0 |
| 6 | 6 | | 100/0 | | 100/0 |
| 7 | 7 | Novec-7200/ | 95/5 | | 100/0 |
| 8 | 8 | MeOH | 95/5 | | 100/0 |
| 9 | 9 | | 90/10 | | 100/0 |
| 10 | 10 | | 90/10 | | 100/0 |
| 11 | 11 | Novec-7200 | 100/0 | | 100/0 |
| 12 | 12 | | 100/0 | | 100/0 |
| 13 | 13 | | 100/0 | | 100/0 |
| 14 | 15 | Novec-7300 | 100/0 | Present | 30/70 |
| 15 | 15 | | 100/0 | | 50/50 |
| 16 | 15 | | 100/0 | | 70/30 |

The obtained composition was evaluated for adhesion to a copper plate, adhesion to a resist plate, flexibility, water and oil repellency, and moisture-proof properties of the coating film. The results are shown in Tables 2 and 3.

The mass ratios of BVE units, PPVE units, MOL units and PFPE when the total mass of the fluorine-containing polymer and PFPE was 100, and the presence or absence of terminal sintering after polymerization are also described in Tables 2 and 3.

TABLE 2

| | | | | Exam- | Exam- | Exam- | Exam- | Exam- | Exam- | Exam- | Exam- | Exam- | Exam- |
|---|---|---|---|---|---|---|---|---|---|---|---|---|---|
| | | | | ple 1 | ple 2 | ple 3 | ple 4 | ple 5 | ple 6 | ple 7 | ple 8 | ple 9 | ple 10 |
| Mass ratio | Fluorine- | BVE unit | | 99 | 95 | 90 | 39 | 54 | 69 | 70 | 66.4 | 62.9 | 70 |
| | containing | PPVE unit | | 0 | 0 | 0 | 60 | 45 | 30 | 25 | 28.6 | 27.1 | 20 |
| | polymer | MOL unit | | 1 | 5 | 10 | 1 | 1 | 1 | 5 | 5 | 10 | 10 |
| | Addition | PFPE | | 0 | 0 | 0 | 0 | 0 | 0 | 0 | 0 | 0 | 0 |
| Aftertreat- | Terminal sintering after polymerization | | | Absent | Absent | Absent | Absent | Absent | Absent | Absent | Absent | Absent | Absent |
| ment | (carboxylic acid modification) | | | | | | | | | | | | |
| Evaluation | Adhesion to | Cross-cut test (first test) | | Class 1 | Class 1 | Class 0 | Class 1 | Class 1 | Class 1 | Class 1 | Class 1 | Class 0 | Class 0 |
| | copper plate | Determination | | S | S | S | S | S | S | S | S | S | S |
| | | Adhesion stability | | A | A | A | A | A | A | A | A | A | A |
| | Adhesion to | Cross-cut test (first test) | | Class 1 | Class 1 | Class 0 | Class 1 | Class 1 | Class 1 | Class 1 | Class 1 | Class 0 | Class 0 |
| | resist plate | Determination | | S | S | S | S | S | S | S | S | S | S |
| | | Adhesion stability | | A | A | A | A | A | A | A | A | A | A |
| | Flexibility | Mandrel test | | A | A | B | A | A | A | A | A | B | B |
| | Water and oil | Contact | Water | 110 | 106 | 103 | 113 | 111 | 109 | 106 | 109 | 108 | 106 |
| | repellency | angle [°] | n- | 52 | 50 | 45 | 66 | 65 | 61 | 58 | 58 | 53 | 52 |
| | | | hexadecane | | | | | | | | | | |
| | Moisture-proof | Cup test | | S | S | A | B | A | S | S | S | A | A |
| | properties | | | | | | | | | | | | |

TABLE 3

| | | | | Example 11 | Example 12 | Example 13 | Example 14 | Example 15 | Example 16 |
|---|---|---|---|---|---|---|---|---|---|
| Mass ratio | Fluorine- | BVE unit | | 42 | 56 | 70 | 30 | 50 | 70 |
| | containing | PPVE unit | | 58 | 44 | 30 | 0 | 0 | 0 |
| | polymer | MOL unit | | 0 | 0 | 0 | 0 | 0 | 0 |
| | Addition | PFPE | | 0 | 0 | 0 | 70 | 50 | 30 |
| Aftertreatment | Terminal sintering after polymerization | | | Absent | Absent | Absent | Present | Present | Present |
| | (carboxylic acid modification) | | | | | | | | |
| Evaluation | Adhesion to | Cross-cut test (first test) | | Class 3 | Class 3 | Class 5 | Class 1 | Class 0 | Class 0 |
| | copper plate | Determination | | B | B | C | S | S | S |
| | | Adhesion stability | | C | C | — | C | C | C |
| | Adhesion to | Cross-cut test (first test) | | Class 5 | Class 5 | Class 5 | Class 1 | Class 0 | Class 0 |
| | resist plate | Determination | | C | C | C | S | S | S |
| | | Adhesion stability | | — | — | — | C | C | C |
| | Flexibility | Mandrel test | | A | A | A | A | A | A |
| | Water and oil | Contact | Water | 116 | 114 | 112 | 116 | 114 | 112 |
| | repellency | angle [°] | n-hexadecane | 66 | 64 | 61 | 66 | 66 | 65 |
| | Moisture-proof | Cup test | | B | A | S | S | S | S |
| | properties | | | | | | | | |

The coating films of the compositions of Examples 1 to 10 exhibited excellent adhesion and adhesion stability to the copper plate and the resist plate, respectively.

On the other hand, the coating films of the compositions of Examples 11 to 13 using fluorine-containing polymers without unit B were poor in adhesion and adhesion stability.

The coating films of the compositions of Examples 14 to 16 in which PFPE was combined with a fluorine-containing polymer that did not have a unit B and had a carboxy group introduced at the end of the main chain exhibited excellent adhesion but poor adhesion stability.

Although several embodiments and examples have been described above, these are presented as representative examples and do not limit the scope of the present invention. Each embodiment and each example described in the present specification can be variously modified within the scope where the effects of the invention are exhibited, and can be combined with other features explained by other embodiments within the implementable scope.

### INDUSTRIAL APPLICABILITY

The polymer of the present invention can form a coating film with excellent adhesion stability.

The composition of the present invention can form a coating film with excellent adhesion stability. By covering the wiring of printed boards, electronic components, and the like with the coating film of the composition of the present invention, corrosion of wiring metals in electronic components, an increase in leakage current, and the like caused by moisture and dust can be prevented, and the long-term reliability of electronic components is improved.

The moisture-proof coating agent of the present invention can form a coating film with excellent adhesion stability.

The article of the present invention exhibits excellent adhesion stability between the base material and the coating film. According to the article of the present invention, corrosion of wiring metals in electronic components, an increase in leakage current, and the like caused by moisture and dust can be prevented, and the long-term reliability of electronic components is improved.

1. A fluorine-containing polymer, comprising:
a unit A comprising a fluorine-containing aliphatic ring structure constituting a main chain; and
a unit B based on a fluorine-containing monomer b comprising an adhesive functional group.

2. The fluorine-containing polymer of claim 1,
wherein a content of the unit B is 0.1 to 20% by mass with respect to the total units constituting the fluorine-containing polymer.

3. The fluorine-containing polymer of claim 1,
wherein the unit A is at least one selected from the group consisting of a unit formed by cyclopolymerization of a diene-based fluorine-containing monomer, and a unit based on a cyclic fluorine-containing monomer.

4. The fluorine-containing polymer of claim 1, wherein the fluorine-containing monomer b is represented by Formula b1:
CX^{a}X^{b}═CX^{c}—R¹—Z Formula b1
wherein
each of X^{a}, X^{b} and X^{c} independently represents a fluorine atom or a chlorine atom, and at least one of X^{a}, X^{b} and X^{c} is a fluorine atom,
R¹ is a divalent perfluoroorganic group which may comprise at least one hetero atom selected from the group consisting of an oxygen atom and a sulfur atom,
Z is CₐH₂ₐOH, COOH, COOR², SO₃H, C_{b}H_{2b}NH₂ or C_{d}H_{2d}CO₂NH₂,
a is an integer from 0 to 6,
R² is an alkyl group having 1 to 12 carbon atoms,
b is an integer from 0 to 6, and
d is an integer from 0 to 6.

5. The fluorine-containing polymer of claim 1, further comprising:
a unit C based on a fluorine-containing monomer c comprising at least one hetero atom selected from the group consisting of an oxygen atom and a sulfur atom, but does not have a fluorine-containing aliphatic ring structure constituting the main chain, and an adhesive functional group.

6. The fluorine-containing polymer of claim 5, wherein a mass ratio of (the unit A)/(the unit C) is 25/75 to 80/20.

7. The fluorine-containing polymer of claim 5, wherein the fluorine-containing monomer c is represented by Formula c1
CX^{d}X^{e}═CX^{f}—C_{c}F_{2c}—Y^{c}—R^{F} Formula c1,
wherein
each of X^{d}, X^{e} and X^{f} independently represents a fluorine atom or a chlorine atom, and at least one of X^{d}, X^{e} and X^{f} is a fluorine atom,
c is an integer from 0 to 4,
Y^{c} is an oxygen atom or a sulfur atom, and
R^{F} is a perfluoroalkyl group having 1 to 10 carbon atoms.

8. A composition, comprising:
the fluorine-containing polymer of claim 1; and
a liquid medium.

9. A moisture-proof coating agent, comprising:
the fluorine-containing polymer of claim 1.

10. A moisture-proof coating agent, comprising:
the composition of claim 8.

11. An article, comprising:
a coating film of the composition of claim 8 on a base material.

12. The article of claim 11, wherein the base material is a printed board.

13. The fluorine-containing polymer of claim 2, wherein the unit A is at least one selected from the group consisting of a unit formed by cyclopolymerization of a diene-based fluorine-containing monomer, and a unit based on a cyclic fluorine-containing monomer.

14. The fluorine-containing polymer of claim 2, wherein the fluorine-containing monomer b is represented by Formula b1:
CX^{a}X^{b}═CX^{c}—R¹—Z Formula b1
wherein
each of X^{a}, X^{b} and X^{c} independently represents a fluorine atom or a chlorine atom, and at least one of X^{a}, X^{b} and X^{c} is a fluorine atom,
R¹ is a divalent perfluoroorganic group which may comprise at least one hetero atom selected from the group consisting of an oxygen atom and a sulfur atom,
Z is CₐH₂ₐOH, COOH, COOR², SO₃H, C_{b}H_{2b}NH₂ or C_{d}H_{2d}CO₂NH₂,
a is an integer from 0 to 6,
R² is an alkyl group having 1 to 12 carbon atoms,
b is an integer from 0 to 6, and
d is an integer from 0 to 6.

15. The fluorine-containing polymer of claim 2, further comprising:
a unit C based on a fluorine-containing monomer c comprising at least one hetero atom selected from the group consisting of an oxygen atom and a sulfur atom, but does not have a fluorine-containing aliphatic ring structure constituting the main chain, and an adhesive functional group.

16. The fluorine-containing polymer of claim 6, wherein the fluorine-containing monomer c is represented by Formula c1
CX^{d}X^{e}═CX^{f}—C_{c}F_{2c}—Y^{c}—R^{F} Formula c1,
wherein
each of X^{d}, X^{e} and X^{f} independently represents a fluorine atom or a chlorine atom, and at least one of X^{d}, X^{e} and X^{f} is a fluorine atom,
c is an integer from 0 to 4,
Y^{c} is an oxygen atom or a sulfur atom, and
R^{F} is a perfluoroalkyl group having 1 to 10 carbon atoms.

17. A composition, comprising:
the fluorine-containing polymer of claim 2; and
a liquid medium.

18. A moisture-proof coating agent, comprising:
the fluorine-containing polymer of claim 2.
